(19) United States
(12) Patent Application Publication
(10) Pub. No.: US 2017/0134016 A1
(43) Pub. Date: May 11, 2017

(54) Reduced Dissipation Switch FET Gate Biasing

(71) Applicant: Peregrine Semiconductor Corporation, San Diego, CA (US)

(72) Inventor: Tero Tapio Ranta, San Diego, CA (US)

(21) Appl. No.: 15/289,768

(22) Filed: Oct. 10, 2016

Related U.S. Application Data
(60) Provisional application No. 62/241,498, filed on Oct. 14, 2015.

(51) Int. Cl. H03K 17/04; H03K 17/687

(52) U.S. Cl. CPC H03K 17/04; H03K 17/6871

(57) ABSTRACT

Systems, methods, and apparatus for biasing transistors of a transistor stack are described. Such biasing can provide reduced RF power dissipation in a corresponding biasing circuit, improved safe low-frequency operation of the transistor stack while maintain a desired switching speed of the transistor stack. Such transistor stack can be used either in a shunted configuration or in a series configuration with the same benefit of reduction in dissipated RF power. Various RF switch configurations using such transistor stacks are also described.

### CROSS REFERENCE TO RELATED APPLICATIONS

The present application claims priority to U.S. provisional Patent Application Ser. No. 62/241,498, filed on Oct. 14, 2015, for a “Reduced Dissipation Switch FET Gate Biasing”, which is herein incorporated by reference in its entirety.

The present application may be related to U.S. Pat. No. 7,960,772 entitled “Tuning Capacitance to Enhance FET Stack Voltage Withstand”, issued on Jun. 14, 2011, the disclosure of which is incorporated herein by reference in its entirety. The present application may also be related to PCT publication number WO2009/108391 entitled “Method and Apparatus for use in Digitally Tuning a Capacitor in an Integrated Circuit Device”, published on Sep. 3, 2009, and to U.S. patent application Ser. No. 13/595,893, entitled “Methods and Apparatuses for Use in Tuning Reactance in a Circuit Device”, filed on Aug. 27, 2012, the disclosures of which are incorporated herein by reference in their entirety.

### TECHNICAL FIELD

Various embodiments described herein relate generally to systems, methods, and apparatus for reducing power dissipation in gate resistors used for biasing a stack of field effect transistors (FETs), transistor stack, used to operate as, for example, a switch. In particular, such transistor stack may be used, either alone or as part of more complex switching circuits, to switch radio frequency (RF) signals in a range of 0.01 MHz to 100 GHz, which can include RF signals used in cellular radio communication systems, and signals in the range of DC to few KHz.

### BACKGROUND INFORMATION

Traditional gate biasing methods for transistor stacks comprising stacked FETs can entail the use of identically sized gate resistors from every gate of a FET of the stack to a common node, such as, for example, a node used to control the states of the stacked transistors used for switching RF signals, which can be represented as an AC ground with respect to the RF signal frequency of operation. Such biasing can result in gate resistors near the top of the transistor stack dissipating significant amount of RF power because they have the highest voltage drop across them. This can lead to design practices where such gate resistor values are increased in order to reduce power dissipation. However, higher gate resistor values can also lead to undesirable longer switching times of the transistor stack and therefore a trade-off between power dissipation in the transistor stack and switching time must be made. It is therefore the object of the present disclosure to propose novel gate biasing methods such as to reduce power dissipation in gate resistors of transistors of a transistor stack while maintaining a same switching time of the transistor stack. Such transistor stack can therefore be advantageously used as a building block to more complex RF circuits and systems, such as RF switching circuits and systems.

### SUMMARY

According to a first aspect of the present disclosure, a circuit arrangement is presented, comprising: a stack of series connected transistors comprising a top transistor, at least one intermediate transistor and a bottom transistor; a plurality of gate resistors, each coupled at a first end to a gate of a respective transistor of said top transistor, at least one intermediate transistor and said bottom transistor; and a resistor ladder string to which a second end of each of said gate resistors is coupled, wherein a bottom of said resistor ladder string is coupled to AC ground.

According to a second aspect of the present disclosure, a method of reduced dissipation FET gate biasing in a stack of series connected transistors is presented, the method comprising: splitting a series of voltage drops in at least one resistor ladder string stage; providing a series of gate voltages to said stack of series connected transistors from said series of voltage drops from said at least one resistor ladder string stage to a gate resistor stage; and approximately equalizing an effective gate impedance from a gate of a transistor to AC ground for transistors in said stack of series connected transistors from said gate resistor stage through said at least one ladder resistor stage to AC ground.

According to a third aspect of the present disclosure, a circuit arrangement is presented, comprising: a stack of series connected transistors comprising a top transistor, at least one intermediate transistor and a bottom transistor; a plurality of gate resistors coupled at a first end to a gate of a respective transistor of said top transistor, at least one intermediate transistor and said bottom transistor; a resistor ladder string to which a second end of each of said gate resistors is coupled, and an AC ground resistively coupled to all gates of the stack of series connected transistors.

According to a fourth aspect of the present disclosure, a method of reduced dissipation FET gate biasing in a stack of series connected transistors is presented, the method comprising: symmetrically splitting a series of voltage drops in at least one resistor ladder string stage from a center AC ground; providing a series of gate voltages to said stack of series connected transistors from said series of voltage drops from said at least one resistor ladder string stage to a gate resistor stage; and approximately equalizing an impedance for transistors in said stack of series connected transistors from said gate resistor stage through said at least one ladder resistor stage to said center AC ground.

According to a fifth aspect of the present disclosure, a circuit arrangement is presented, comprising: a stack of series connected transistors; and a resistor tree, wherein the resistor tree comprises a plurality of resistor levels, each resistor level having one or more resistors each separately connected to two or more resistors of a subsequent resistor level, the resistors of the last resistor level each being a gate resistor connected to a respective gate of a plurality of transistors of the stack of series connected transistors, and wherein the one or more resistors of a first resistor level are a single resistor connected to two or more resistors of the second resistor level at one end and to AC ground at the other end.

According to a sixth aspect of the present disclosure, a method of reduced dissipation FET gate biasing in a stack of series connected transistors is presented, the method comprising: symmetrically splitting in levels a series of voltage drops in a resistor tree; providing a series of gate voltages to said stack of series connected transistors from said series of voltage drops from said resistor tree to a gate resistor stage; and approximately equalizing an impedance for transistors in said stack of series connected transistors from said gate resistor stage through said resistor tree to AC ground.

### BRIEF DESCRIPTION OF THE DRAWINGS

FIG. 1A is a simplified circuit diagram of a prior art gate biasing of an exemplary transistor stack. The exemplary transistor stack depicted in FIG. 1A comprises 8 stacked FETs and 8 gate resistors used for biasing the FETs.

FIG. 1B is a representation of a circuit layout of the gate resistors used in the transistor stack FIG. 1A.

FIG. 1C is an RF equivalent circuit representation of the prior art transistor stack configuration depicted in FIG. 1A showing an exemplary voltage distribution across the various nodes of the transistors of the transistor stack when the transistor stack is in the OFF state.

FIG. 1D is an extension representation of the circuit of FIG. 1C where the number of transistors in the transistor stack is n, when the transistor stack is in the OFF state.

FIG. 1E is an RF equivalent circuit representation of the prior art transistor stack including the gate resistors (OFF state).

FIG. 1F shows an exemplary single pole double throw RF switch comprising series and shunt components, each component comprising a transistor stack and corresponding biasing networks.

FIG. 2 is a graphical representation of plots for the low-frequency corners for the prior art gate biasing configuration of the transistor stack depicted in FIG. 1A.

FIG. 3A is a simplified circuit diagram according to an embodiment of the present disclosure of a reduced dissipation tree gate biasing configuration of an exemplary transistor stack. The exemplary transistor stack depicted in FIG. 3A comprises eight stacked transistors, and the reduced dissipation tree gate biasing comprises a resistor ladder string coupled to gates of the transistors of the transistor stack via gate resistors.

FIG. 3B is a representation of a circuit layout of the reduced dissipation tree used in the embodiment depicted in FIG. 3A.

FIG. 3C shows an RF circuit equivalent of the transistor stack depicted in FIG. 3A expanded to n transistors in the transistor stack, when the transistor stack is in the OFF state (e.g. all transistors in the transistor stack are OFF).

FIG. 4 is a graphical representation of plots for the low-frequency corners for the reduced dissipation tree gate biasing configuration according to the various embodiments of the present disclosure.

FIG. 5 is a comparison chart of a performance of the prior art gate biasing configuration versus a performance of the reduced dissipation tree gate biasing configuration.

FIG. 6A shows the series connected transistor stack (23) of FIG. 1F including details on coupled impedances to the transistor stack.

FIG. 6B shows an exemplary implementation of a digitally tunable capacitor (DTC), where the DTC comprises a plurality of selectable capacitor bits, each capacitor bit comprising a transistor stack in series connection with one or more capacitors, the transistor stack being biased by way of a reduced dissipation tree gate biasing configuration according to the various embodiments of the present disclosure.

FIGS. 7A-7B is a simplified circuit diagram according to an embodiment of the present disclosure of a symmetric reduced dissipation tree gate biasing configuration of exemplary transistor stacks comprising an odd number of transistors (FIG. 7A) and an even number of transistors (FIG. 7B).

FIG. 8A is a simplified circuit diagram according to an embodiment of the present disclosure of a 3-level, secondary tree symmetric reduced dissipation tree gate biasing configuration of exemplary transistor stacks.

FIG. 8B is a simplified circuit diagram according to an embodiment of the present disclosure of a 2-level, tertiary tree symmetric reduced dissipation tree gate biasing configuration of exemplary transistor stacks.

FIG. 8C is a simplified circuit diagram according to an embodiment of the present disclosure of a 2-level, mixed tree symmetric reduced dissipation tree gate biasing configuration of exemplary transistor stacks.

FIG. 8D is a simplified circuit diagram according to an embodiment of the present disclosure of an arbitrary tree symmetric reduced dissipation tree gate biasing configuration of exemplary transistor stacks.

FIG. 9 depicts an exemplary power reduction scheme according to the present disclosure of the 3-level, secondary tree of FIG. 8A.

Like reference numbers and designators in the various drawings indicate like elements.

### DETAILED DESCRIPTION

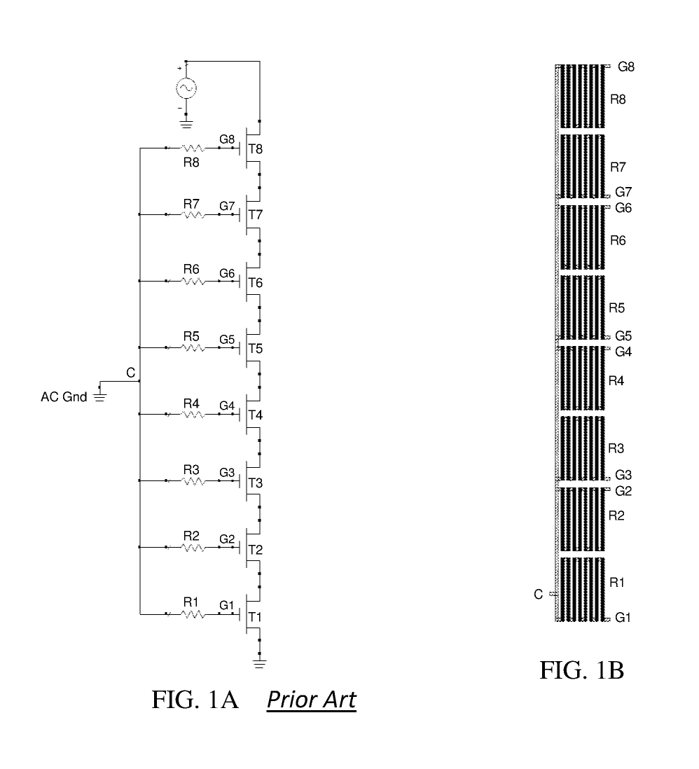

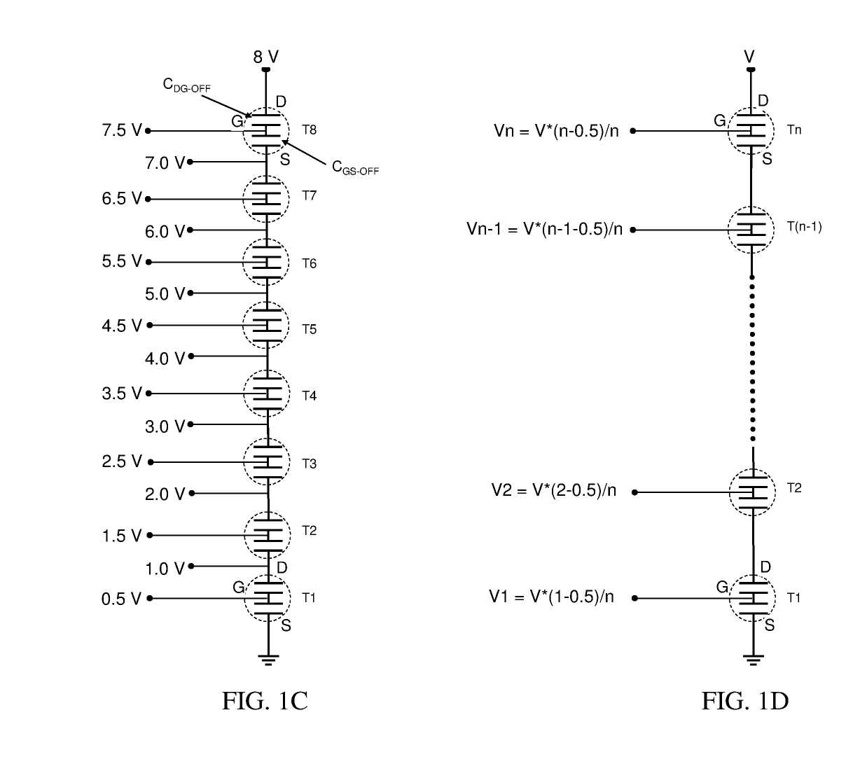

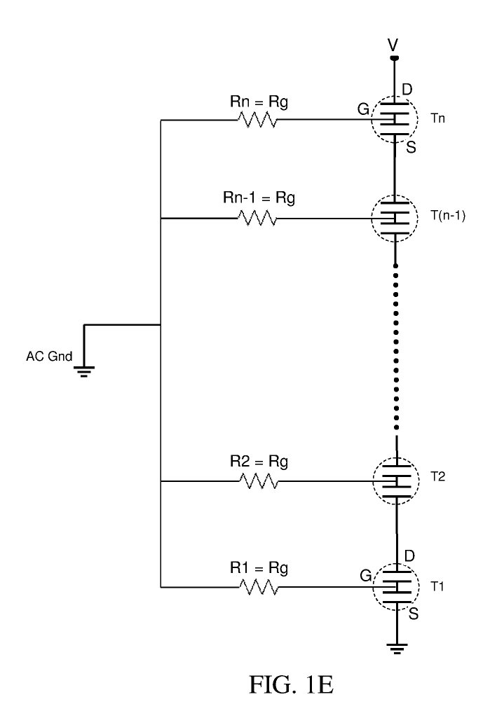

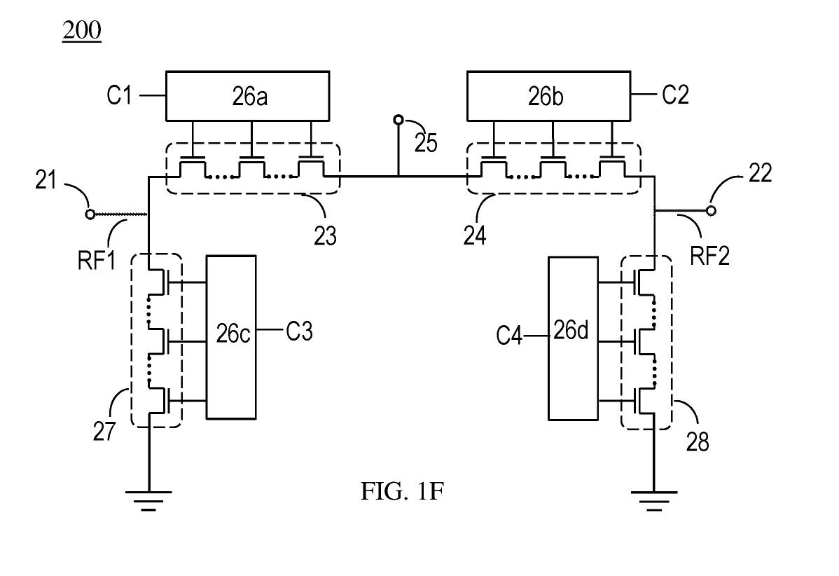

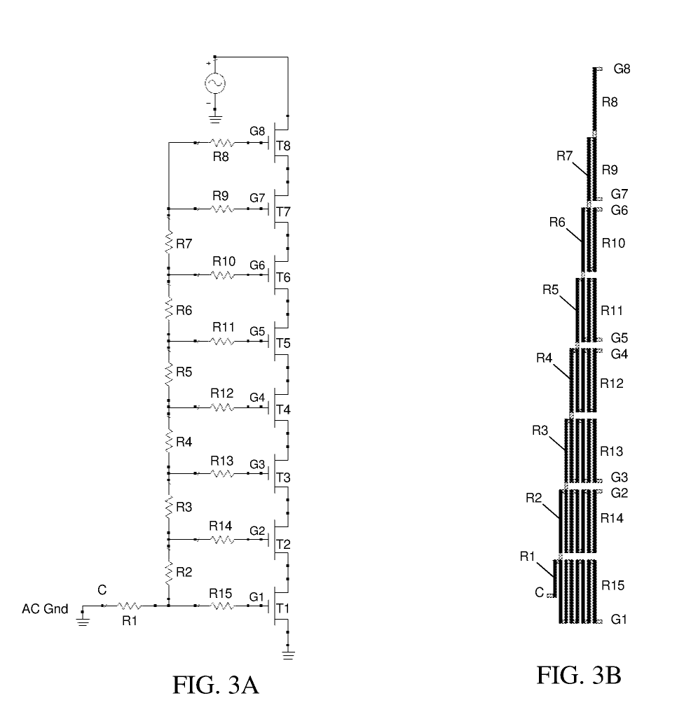

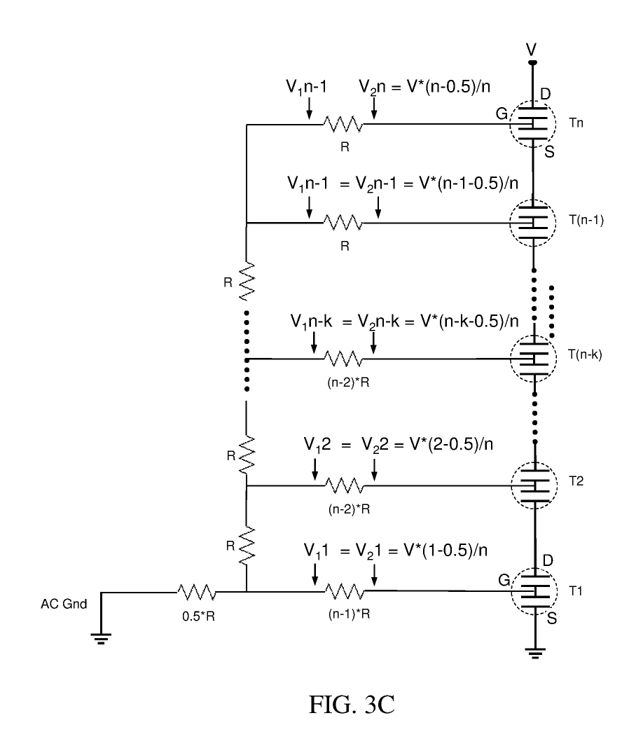

A novel resistor tree approach (e.g. FIG. 3A later described) for biasing gates of a stack of series connected transistors, a transistor stack, is proposed that minimizes the sum of power dissipation in resistors used for biasing the gates of the transistors of the transistor stack while having the same effective gate resistor value used in a traditional gate biasing configuration (e.g. prior art, FIG. 1A) for equal switching time (speed). According to an exemplary embodiment of the present disclosure, a reduction in power dissipation can be achieved by coupling a voltage at a gate of a FET at the top of the transistor stack to gates of other transistors of the transistor stack via a resistor tree configuration. According to the various embodiments of the present disclosure, such resistor tree can include a plurality of gate resistors coupled to a resistor ladder string, and/or coupled to other resistor string configurations. During operation, while the transistor stack is OFF (all constituent transistors are OFF), an RF voltage that is applied to the top of the transistor stack is coupled to the gates of the transistors of the transistor stack. The resistor tree can include a resistor ladder string whose tap points can be selected to have identical voltages compared to the coupled voltages at the gates of FETs in the transistor stack. Finally, a series gate resistor can be connected from each tap point to a corresponding FET gate, with a resistance value selected to provide an identical path resistance from the FET gate to the common node AC for each of the FETs in the transistor stack. This can result in no power being dissipated in any of the series gate resistors except for the resistor ladder string connected to the top FET in the transistor stack. This novel resistor tree configuration can provide a reduction in RF power dissipation with respect to prior art embodiments of gate biasing resistors. Additionally, and as will be described in later sections of the present disclosure, such novel transistor biasing using the proposed resistor tree configuration can provide reduced and identical RF low frequency corners for equal voltage division for every transistor in the transistor stack.

The person skilled in the art will understand that the transistor stack described herein can operate in either of an ON state or an OFF state, where during the ON state, all the transistors of the transistor stack are conducting (ON), and during the OFF state, all the transistors of the transistor stack are not conducting (OFF). The person skilled in the art will know how to use the various embodiments of the present disclosure in more complex RF circuits where switching of a conduction path to an RF signal is desired, the conduction path passing through the transistor stack according to the present embodiments.

FIG. 1A shows a prior art configuration for gate biasing of a transistor stack (series connected transistors connected in a source to drain configuration operating as, for example, a switch) where all the gate resistors (R1-R8) used for biasing of the transistors have an equal resistance value (Rg). Each gate biasing resistor (R1-R8) is connected between a gate of a transistor of the transistor stack (T1-T8) on one side, and a common node on the other side. Although the common node in FIG. 1A is indicated as a common AC ground node, the skilled person readily knows that such common node can be represented by a voltage source adapted to provide a suitable gate biasing voltage to each of the transistors (T1-T8) of the transistor stack, which can have an associated switching frequency. Such gate biasing voltage can be a voltage which switches between two states; a high state and a low state, each representing an ON or OFF state of the transistors of the transistor stack (and therefore of the transistor stack). Switching between the two states in such a transistor stack can be performed at frequencies which are orders of magnitude smaller than the frequency of the RF signal applied to the drain of the top transistor in the transistor stack.

FIG. 1B shows a representation of an actual physical layout of the gate biasing resistors (R1-R8) used in the prior art transistor stack configuration of FIG. 1A. Each gate resistor (R1-R8) used for biasing of the transistor stack is composed of a plurality of segments of resistive material (e.g. having a unit resistance) connected with one another to form a desired total resistance value of the gate resistor. In the prior art embodiment of the transistor stack depicted in FIG. 1A, all resistors have a same resistance value and are therefore represented by a same number of equally sized resistive segments in the resistor physical layout depicted in FIG. 1B. In the exemplary case depicted in FIG. 1B, each gate resistor is composed of eight equally sized resistive segments and connected on one side to gates of transistors (T1-T8) of FIG. 1A via nodes (G1-G8) and on the other side to a common voltage node (e.g. AC ground, gate biasing voltage) via common node C of the gate biasing resistors.

As known to a person skilled in the art, a stack of transistors can be used for a power handling requirement of the transistor stack in the “OFF” state, as a high voltage component of a transmitted RF signal can be higher than a breakdown voltage of a single transistor. By stacking several same transistors, the high voltage of the RF signal can be evenly distributed across the transistors of the transistor stack, so as any given transistor of the transistor stack sees a voltage not higher than its breakdown voltage across it (e.g. between its drain and source terminals). In cases where parasitic capacitance affects such even distribution of the RF voltage across the transistor stack, compensation capacitors can be used to obtain the desired even distribution, such as described, for example, in U.S. Pat. No. 7,960,772, issued on Jun. 14, 2011, entitled “Tuning Capacitance to Enhance FET Stack Voltage Withstand”, which is incorporated herein by reference in its entirety.

FIG. 1F shows an exemplary RF switch (200) configuration using series transistors (23, 24) and shunt transistors (27, 28), where each of the series/shunt transistors can be a transistor stack, such as transistors (T1-T8) of FIG. 1A. The single pole double throw (SPDT) RF switch of FIG. 1F can switch one of RF1 and RF2 signals provided at switch terminals (21, 22) to the common output terminal (25), under control of gate bias voltages C1-C4 provided to the gate biasing networks (26a-26d) coupled to the gates of the series/shunt transistor stacks (23, 24, 27, 28). As previously noted in the present disclosure, such gate bias voltages can be represented by an AC ground common node provided to each of the gate biasing networks. In an exemplary prior art configuration, the gate biasing networks can be the gate resistors (R1-R8) depicted in FIG. 1A and each of the series/shunt transistor stacks (23, 24, 27, 28) can be the stacked transistors (T1-T8) of FIG. 1A. The person skilled in the art will recognize that the various gate biasing configurations according to the various embodiments of the present disclosure can be used to provide a reduced power dissipation in a transistor stack, such as the RF switch (200) of FIG. 1F. Furthermore, due to the reduction in the low-frequency corner of the transistors of a transistor stack provided by the various embodiments according to the present disclosure, such transistor stack can handle a lower frequency RF signal at the same power level.

FIG. 1A can represent a shunt or a series component of an RF switch (200) as shown in FIG. 1F. When the series component (23, 24) conducts, the adjoining shunt component (27, 28) does not conduct and must therefore tolerate an RF voltage at the drain of the top transistor T8. In this condition, shunt transistors (T1-T8) are OFF and the off capacitance of the transistors (e.g. off capacitance between drain-gate, and off capacitance between gate-source) can provide for the even distribution of the voltage at the drain of T8 across transistors (T1-T8). This is depicted in FIG. 1C, which shows the RF electrical equivalent of transistors (T1-T8) in the OFF condition, which can each be represented by a drain-gate capacitor C_{DG-OFF} between the drain D and the gate G junctions of the transistor, and a gate-source capacitor C_{GS-OFF} between the gate G and the source S junctions of the transistor. When such capacitances are equal, equal distribution of a voltage at the drain of the top transistor, T8, of the transistor stack, across all the transistors of the transistor stack can be obtained, as represented by the various voltages in FIG. 1C.

With further reference to FIG. 1C, it is assumed that the RF voltage at the drain D of the top transistor T8 has an arbitrary instantaneous RF value of 8 volts. As shown in FIG. 1C, voltage distribution of the RF voltage at the top transistor T8 across all the transistors of the transistor stack yields to a voltage at the gates of the transistors of the transistor stack equal to (7.5V, 6.5V, 5.5V, 4.5V, 3.5V, 2.5V, 1.5V, 0.5V) for gates of transistors (T8, T7, . . . , T1) respectively. A person skilled in the art will realize that other values for the voltage at the drain D of the top transistor T8 are also possible which can lead to corresponding proportional voltages at the gates of the transistors of the transistor stack according to a same voltage distribution scheme FIG. 1D is an RF equivalent circuit of a transistor stack (without gate resistors) in the OFF condition comprising n transistors (e.g. FETs). FIG. 1D further shows values of voltages at the gates of the transistors of the transistor stack as a function of a voltage V of the RF signal seen at the drain D of the top transistor Tn of the transistor stack. FIG. 1D is an extension of FIG. 1C (e.g. from 8 transistors to n transistors) and showcases the equal voltage distribution across the transistors of the transistor stack when in the OFF condition. The person skilled in the art is well aware of this concept and no further explanation should be necessary. As shown in FIGS. 1C and 1D, voltages at the gates of the transistors of the transistor stack get higher as a function of the position of a transistor in the transistor stack. The topmost transistor has the higher RF gate voltage, and the lower transistor of the transistor stack has the lower RF gate voltage.

It should be noted that the circuits represented in FIGS. 1C-1E are representative of the transistor stack in the RF domain when the transistor stack is in the OFF condition, and the voltages at the various points represented in such figures are RF voltages based on the RF voltage of the RF signal present at the drain of the top transistor of the transistor stack. In particular, voltages at the gates of the transistors are fed to the gate resistors, as depicted in FIG. 1E, where each gate resistors is connected to a common node (e.g. AC ground) as depicted in FIG. 1E. It is within the ability of the skilled person to deduce the power dissipated by each gate resistor in the transistor stack as a function of the resistance of the gate resistor and the RF voltage at the corresponding gate. Such power dissipation can be provided by the following equation (1):

$${P}_{k} = \frac{{V}_{k}^{2}}{{R}_{g}} \qquad ( 1 )$$

where:

k=[1, n] represents position of a transistor in the transistor stack, n being the topmost;

Pₖ is the power dissipated by the resistor at the gate of the k^{th} transistor of the transistor stack;

R_{g} is the resistance value of the gate resistor, where all gate resistors have a same value; and

Vₖ is the instantaneous RF voltage across the gate resistor positioned at the gate of the k^{th} transistor of the transistor stack.

Based on the above equation (1) and the RF voltage at the gates of the transistors of the transistor stack, the skilled person quickly realizes that power dissipation is higher for the gate resistors of the higher transistors (closer to the top transistor) of the transistor stack. As a matter of fact, power dissipation in the resistor at the gate of a transistor of the transistor stack is an increasing function of the position of the transistor in the transistor stack. The total power dissipation P_{D} of the resistors when in the OFF condition can be calculated as a sum of the power dissipations Pₖ as represented by the following equation (2):

P_{D}=Σₖ₌₁ⁿPₖ (2)

where n is the number of transistors in the transistor stack.

By plugging the value of Vₖ into equation (1) and then the resultant power Pₖ into equation (2), one can obtain the total power dissipation value in the gate biasing resistors of the prior art embodiment depicted in FIG. 1A:

$${P}_{D} = {\sum }_{k = 1}^{n} \frac{{V}_{k}^{2}}{{R}_{g}} = {\sum }_{k = 1}^{n} \frac{{( V \cdot \frac{k - 0.5}{n} )}^{2}}{{R}_{g}} \qquad ( 2.1 )$$

Therefore, for the case of the prior art gate biasing configuration depicted in FIG. 1A, total RF power dissipation can be provided by the following expression:

$${P}_{D} = \frac{{V}^{2}}{{n}^{2} {R}_{g}} {\sum }_{k = 1}^{n} {( \frac{2 k - 1}{2} )}^{2} = \frac{{V}^{2}}{{R}_{g}} ( \frac{4 {n}^{2} - 1}{12 n} ) \qquad ( 2.2 )$$

In order to reduce the power dissipation in the resistors at the gates of the transistors of the transistor stack, the prior art embodiment attempts to maximize the value of the resistance value Rg, since for a given RF gate voltage, a higher resistance value of the gate resistor reduces the power dissipation in the gate resistor, as described by equation (1). However, the value of the gate resistance can affect a switching time (speed) of a transistor of the transistor stack, as controlled by the switching bias voltage applied at the gate of the transistor. The gate resistor resistance Rg in combination with a gate capacitance of the transistor can create an R-C time constant which controls the rate at which the state of the transistor can effectively be switched under control of the bias voltage. For this, a lower R-C time constant for a faster switching speed (reduced switching time) of the transistor can be desirable, and therefore a lower value of the gate resistance Rg can be desirable. Therefore, in the prior art embodiment depicted in FIG. 1A, a compromise between RF power dissipation in the gate resistors of the stacked transistors and the switching speed of the transistor stack should be made.

With further reference to FIGS. 1C and 1D, equal voltage distribution of a voltage of an RF signal at the drain of the top transistor across the transistors of the transistor stack in the OFF condition is provided. For lower frequency RF signals, the impedance seen across the transistors of the stack can increase and may cause the gate resistors to impact the RF voltage division across the stack. This can change the RF voltage at the gate to a non-uniform division and can therefore gradually cause a collapse of the equal voltage distribution across the transistors of the transistor stack. Such collapse can cause the one or more transistors to see a larger amount of the total RF voltage. Such larger amount of the total RF voltage can in turn cause a transistor to fail as the larger voltage can be larger than the breakdown voltage of the transistor. Therefore, a transistor stack, such as one depicted in FIG. 1A, can have a safe operating frequency of an RF signal, which can be determined as a function of the gate resistor values and the off capacitance of the constituent stacked transistors. Accordingly, a low-frequency corner can be defined which represents a specific RF frequency when a voltage across (e.g. drain-to-source) a set of transistors of the transistor stack collapses to half a voltage of a nominal value. The nominal value can be considered to be the value representing equal voltage distribution across all the transistors of the transistor stack which can be obtained at higher operating frequencies.

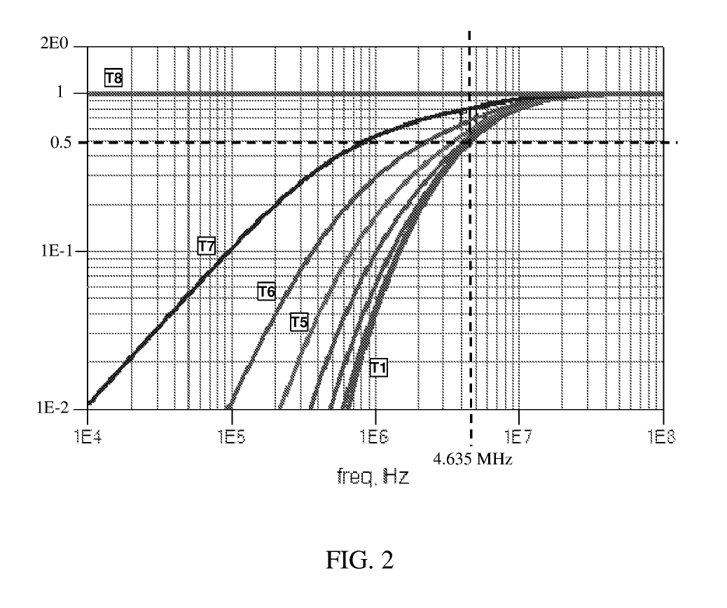

FIG. 2 represents logarithmic scale plots of the RF signal low-frequency corners at the drain nodes of the various transistors of the prior art transistor stack depicted in FIG. 1A. For each drain node of a transistor of the transistor stack (T1-T8), collapse of the voltage across the transistor (e.g. as measured at the drain node of the transistor) is plotted as a function of the RF signal frequency. As can be seen in FIG. 2, RF voltage at a drain node of the topmost transistor T8 remains constant at a corresponding nominal value throughout the frequency range plotted. Voltage at a drain node of the next higher transistor T7 collapses at a frequency which is lower than 1 MHz. When collapse at the drain node of transistor T7 occurs, a voltage across transistor T8 can be higher than a corresponding breakdown voltage which can cause damage to T8. Similarly, when collapse at the drain node of transistor T6 occurs (e.g. around 2 MHz), a voltage across one or both of transistors T8 and T7 can be higher than a corresponding breakdown voltage of such transistors and therefore one or both of T8 and T7 can get damaged. At the other extreme, voltage at a drain node of the lower transistor T1 collapses first (e.g. before all the other transistors of the stack) as the frequency of operation decreases at a frequency of 4.635 MHz, the voltage reaches a value which is half the nominal voltage on the drain of the transistor T1. As can be seen in the various plots of FIG. 2, collapsing of the voltages occur at different points of the frequency scale and in an order corresponding to the position of the transistor in the transistor stack (from lower to higher as frequency decreases). As the voltage across transistor T1 gets smaller, voltage across other transistors in the transistor stack can increase which can therefore cause breakdown in one or more of the transistors (T2-T8) of the transistor stack. Therefore, in the prior art embodiment depicted in FIG. 1A, collapsing behavior of the lower transistor T1 of the stack can determine a corresponding safe lower RF signal frequency of operation of the transistor stack (e.g. 4.635 MHz). It should be noted that, for the sake of clarity, the transistor drain voltages plotted in FIG. 2 are normalized voltages obtained by dividing the voltage at a drain of each transistor of the transistor stack by the number of transistors of the transistor stack below that specific transistor (including that specific transistor). In addition to transistor breakdown, an unequal voltage division has other negative performance implications, such as degraded harmonic performance, increased spurious emissions, etc.

Via simulation results, the Applicant of the present disclosure has established that for a given transistor design of the transistor stack, the safe lower RF signal frequency of operation, as determined, for example, via the RF signal low-frequency corner plots, can be adjusted by changing the resistance Rg value of the gate resistors of the transistor stack. Higher gate resistance values can decrease the value of the safe RF frequency of the transistor stack and therefore allow the transistor stack to operate at a lower RF signal frequency. However, as previously mentioned, such higher resistance can adversely affect the switching speed of the transistor stack.

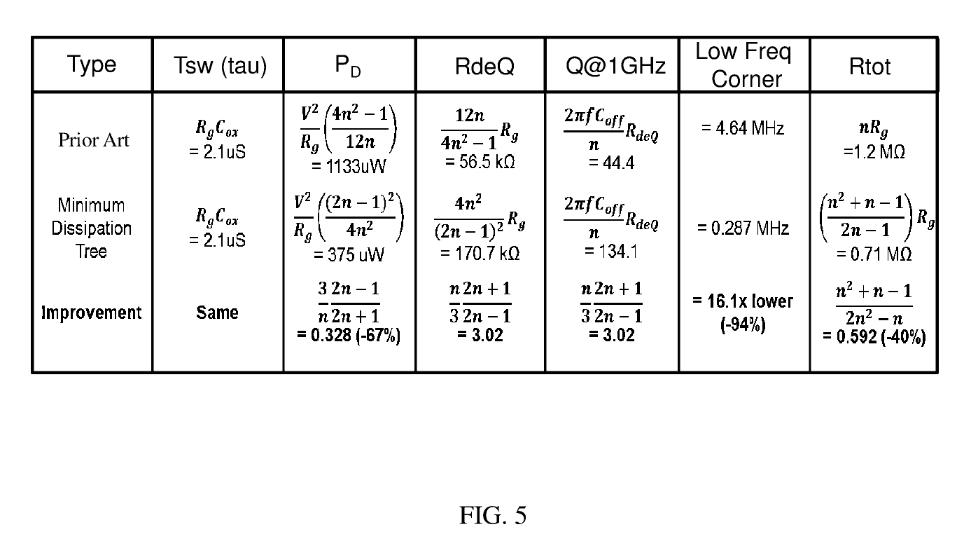

FIG. 3A represents a circuit configuration of a transistor stack according to an embodiment of the present disclosure where a resistor ladder string (R1, R2, . . . , R7) is used in a corresponding gate biasing circuit. The gate biasing circuit used in the exemplary stack-of-8 transistor configuration depicted in FIG. 3A can provide a same total resistance (e.g. total resistance from a transistor gate to the common AC ground) used to determine the switching time constant (and therefore switching speed), as compared to the prior art configuration depicted in FIG. 1A, for a reduced RF power dissipation, a reduction by a factor of 16 times of the low-frequency corner, 3 times higher FET stack quality factor (described later in reference to FIG. 5), and 40% smaller die layout area by virtue of a lower total resistance in the gate biasing circuit. The Applicant of the present disclosure has established, via a minimization function, that such gate biasing configuration using the resistor ladder string (R1, R2, . . . , R7) coupled to gate resistors (R8-R15) can provide a reduced power dissipation in the resistors used in the corresponding biasing circuit and have therefore labelled such configuration a “reduced dissipation tree”. Via same minimization function, the Applicant has established other possible tree configurations, with different resistor values which, while not providing the same reduced power dissipation, can provide improvements in power dissipation, low RF frequency corner, FET stack quality factor, and die layout area when compared to the prior art embodiment gate biasing configuration for a transistor stack depicted in FIG. 1A.

In the exemplary stack-of-8 configuration depicted in FIG. 3A, according to an embodiment of the present disclosure, each resistor of the resistor ladder string (R1, R2, . . . , R7), except R1 (connected to the AC ground) which has a resistance value of 0.5*R, has a same value resistance R. The gate resistors (R8, R9, . . . , R15) connected to the gate of the transistors of the stack (T8, T7, . . . , T1) respectively, have a resistance value equal to (R, R, 2*R, 3*R, . . . , 7*R) respectively. The value of the resistance R is chosen such that the total resistance from a gate of a transistor of the transistor stack to the AC ground is same as the Rg value used in the prior art configuration depicted in FIG. 1A. Such choice of resistance can provide a same switching speed of the transistor stack as compared to the switching speed provided by the prior art configuration depicted in FIG. 1A. For example, total resistance from the gate of T8 to the AC ground is the resistance of R8+R7+ . . . +R2+R1 which is set to be equal to Rg. Therefore, R+R+ . . . +R+0.5R=7.5R=Rg, which leads to R=Rg/7.5. For such value of R, one can easily see that the total resistance (effective impedance) from any gate of the stack is Rg. For example, the total resistance from the gate of T1 is R15+R1=7.5R=Rg.

Similar to FIG. 1B, FIG. 3B shows a representation of an actual physical layout of the biasing resistors (R1-R15) used in the exemplary stack-of-8 transistor stack configuration of FIG. 3A. Each resistor (R1-R15) used for biasing of the transistor stack is composed of a one or more segments of resistive material (e.g. having a unit resistance) connected with one another to form a desired total resistance value of the resistor. In the exemplary embodiment according to the present disclosure of the transistor stack depicted in FIG. 3A, all of the resistors (R2, . . . , R7) of the resistor ladder string not directly connected to the AC ground have a same resistance value, indicated by a single resistive segment in FIG. 3B. Resistor R1 has a resistance value half of the other resistors in the tree, which is represented by half a resistive segment. Gate resistors (R8, . . . , R15) have different resistance values, each an integer factor of the same resistance value of resistors (R2, . . . , R7) of the resistor ladder string not directly connected to the common AC ground, and therefore are shown as having one resistive segment for R8 and R9, to seven resistive segments for R15. Connections to the gates of the transistor (T1-T8) of the transistor stack are provided via nodes (G1-G8) depicted in FIG. 3B and a connection to the AC ground is provided via common node C coupled to the resistor R1 of the resistor ladder string, as depicted in FIG. 3B.

As seen in FIG. 3B, for a same switching speed of the transistor stack (e.g. a same total (effective) gate resistance to the common node), total real estate used, for example on a chip, for the gate biasing resistors is approximately half of the total real estate used in the prior art embodiment depicted in FIG. 1B. This in turn can advantageously be used to fabricate a smaller size switch device with reduced RF power dissipation.

The person skilled in the art can readily use the teachings according to the various embodiments of the present disclosure to expand the gate biasing circuit depicted in FIG. 3A to implement a transistor stack comprising a larger or smaller number n (with n≧1) of a stack of series connected transistors, while keeping the same benefits of the teachings as described in the previous sections. Corresponding resistance values can be scaled to the number of transistors in the transistor stack.

The total resistance (sum of all resistor values) is proportional to the physical die area occupied by resistors. The total resistance used in the reduced dissipation tree configuration, R_{T}, can be expressed by the following equations:

$${R}_{T} = ( n - 0.5 ) R + {\sum }_{k = 1}^{n - 1} ( kR ) \\ and \\ R = \frac{{R}_{e}}{n - 0.5} \qquad ( 3 )$$

where Rₑ is the effective gate resistance of the reduced power dissipation such that the switching speed and low-frequency corner of the switch is the same as the prior art, and Rₑ is the value for R2-R7 in the reduced power dissipation embodiment of FIG. 3A.

Considering the total resistance with respect to only the effective gate resistance, the total resistance can be simplified to:

$${R}_{T} = ( 1 + {\sum }_{k = 1}^{n} ( \frac{n - k}{n - 0.5} ) ) {R}_{e} = ( \frac{{n}^{2} + n - 1}{2 n - 1} ) {R}_{e} \qquad ( 3.1 )$$

R_{T} can be simplified, for large value of n to:

R_{T}≈(0.75+0.5n)Rₑ (3.2)

By contrasting R_{T} from expression (3.2) to the total resistance value n*Rg used in the prior art resistor gate biasing depicted in FIG. 1A, the person skilled in the art can appreciate the reduction in die physical layout size by using the reduced dissipation tree configuration according to the present disclosure over the prior art embodiment of the resistor gate biasing configuration (since n*Rg>R_{T}), when using resistor values that achieve the same switching speed.

FIG. 3C shows an RF circuit equivalent of the transistor stack depicted in FIG. 3A expanded to n transistors (T1, T2, . . . , Tn) in the transistor stack, when the transistor stack (e.g. switch) is in the OFF state (e.g. all transistors in the stack are OFF). The transistors are represented by the corresponding capacitors as previously described with respect to FIGS. 1C-1E. According to an embodiment of the present disclosure, the gate biasing circuit of FIG. 3A, whose RF equivalent is depicted in FIG. 3C, is configured to dissipate a reduced amount of RF power while maintaining a given Rₑ (effective R_{g}). Such reduced dissipation power is obtained via methodic selection of the resistor values of the gate biasing circuit, which comprises the gate resistors (e.g. R8, . . . , R15 of FIG. 3A) which are directly connected to the transistors of the transistor stack, and the resistor ladder string (e.g. R1, . . . , R7 of FIG. 3A) which is coupled to the transistor stack via the gate resistors. In particular, such selection allows for essentially zero power dissipation in the gate resistors directly connected to the transistors (T1, T2 . . . , Tn-1) of the transistor stack, except in the gate resistor directly connected to the topmost transistor Tn. This selection is shown in FIG. 3C, where relative values of the resistors of the gate biasing circuit according to the embodiment of the present disclosure are shown. Also shown in FIG. 3C are the voltages at the terminals of the gate resistors of the biasing circuit which are a function of the RF voltage V at the drain of the topmost transistor of the transistor stack (or alternatively a function of a difference between an RF voltage at the drain of the topmost transistor T8 and an RF voltage at the source of the bottommost transistor T1). As can be seen in the FIG. 3C, voltages at each terminal of the gate resistors directly connected to the gate of (T1, T2, . . . , Tn-1) are the same level for a given gate resistor and therefore these gate resistors do not dissipate any RF power as a voltage drop across such gate resistors is zero. Therefore, RF power dissipation in the gate biasing circuit depicted in FIG. 3A is solely provided by power dissipation in the gate resistor of the topmost transistor of the transistor stack Tn and by power dissipation in the resistors of the resistor ladder string coupled to the gate resistors. It should be noted that while reduced power dissipation in the gate resistors can be obtained by providing zero voltage drop across such resistors (R9, . . . , R15), alternative embodiments where the voltage drop across one or more of the gate resistors (R9, . . . , R15) is not zero, can also be envisioned. In such embodiments, a voltage at a terminal of a gate resistor not connected to the gate of a corresponding transistor (e.g. (T1, T2 . . . , Tn-1) is smaller than the voltage at the gate of the transistor. Therefore, a voltage drop across such gate transistor is not zero, and less than the voltage at the gate of said transistor. According to some embodiments, such voltage drop can be approximately zero.

Based on the values of voltages at each of the various resistors of the gate biasing circuit of FIG. 3A, whose RF equivalent is depicted in FIG. 3C, power dissipation across the resistors can be derived. For example:

power dissipation P_{tree[n]} in the gate resistor of the topmost transistor Tn is:

$${P}_{tree [ n ]} = \frac{{( {V}_{n} - {V}_{n - 1} )}^{2}}{R} \qquad ( 4 )$$

power dissipation in the top resistor of the tree connected between the gate resistors of transistors Tₙ₋₁ and Tₙ₋₂ is:

$${P}_{tree [ n - 1 ]} = \frac{{( {V}_{n - 1} - {V}_{n - 2} )}^{2}}{R} \qquad ( 5 )$$

power dissipation in the resistor of the tree connected between the gate resistors of transistors T₂ and T₁ is:

$${P}_{tree [ 2 ]} = \frac{{( {V}_{2} - {V}_{1} )}^{2}}{R} \qquad ( 6 )$$

and power dissipation in the bottom resistor of the tree connected to the common node (e.g. AC ground) is:

$${P}_{tree [ 1 ]} = \frac{{( {V}_{1} )}^{2}}{0.5 * R} \qquad ( 7 )$$

In general, power dissipation Pₖ in a resistor of the tree connected between the gate resistors of two adjacent transistors of the stack Tₖ and Tₖ₋₁ where k≧2 and in the gate resistor of the top most transistor T_{N}, can be provided by the following equation:

$${P}_{k} = \frac{{( {V}_{k} - {V}_{k - 1} )}^{2}}{R} \qquad ( 8 )$$

where Vₖ is the RF voltage at the gate of Tₖ, with k=1, . . . , n.

The total power dissipation in the reduced power dissipation gate biasing circuit, including in the top resistor, according to the embodiment of the present disclosure can be expressed by the equation (2) above, where P₁ is provided by (7) and Pₖ for k≧2 is provided (8).

As one can design the total resistance to the common node (e.g. AC ground) from the gate of the topmost transistor Tn to be Rg, and no power dissipation is provided by the lower gate resistors (e.g. associated to transistors T₁-T₍ₙ₋₁₎), total power dissipation in the gate biasing circuit of FIGS. 3A and 3C, can be equal to the power dissipation of the voltage at the gate of the topmost transistor into a resistance of value Rg. Therefore, total power dissipation in the reduced power dissipation configuration according to the embodiment of the present disclosure can be provided by the following expression:

$$\begin{matrix}{P}_{Tdiss} = \frac{{( {V}_{n} )}^{2}}{Rg} ; \\ since \text{:} {V}_{n} = V * \frac{( n - 0.5 )}{n} & ( 9 ) \\ then \text{:} {P}_{Tdiss} = \frac{{V}^{2}}{{R}_{g}} * {( \frac{n - 0.5}{n} )}^{2} = \frac{{V}^{2}}{Rg} ( \frac{{( 2 n - 1 )}^{2}}{4 {n}^{2}} ) & ( 10 )\end{matrix}$$

By contrasting expressions (2.2) and (10), the person skilled in the art can appreciate the reduction in power dissipation provided by the reduced dissipation tree configuration according to the present disclosure over the prior art embodiment of the resistor gate biasing configuration.

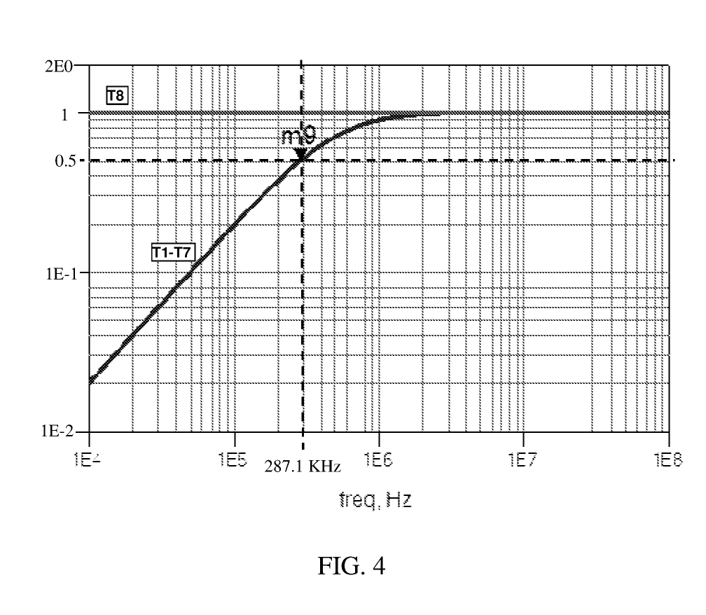

FIG. 4 represents logarithmic scale plots of the low-frequency corners at the drain nodes of the various transistors of the reduced dissipation tree biasing configuration according to the embodiment of the present disclosure. As can be seen in FIG. 4, drain nodes of all the transistors of the transistor stack (e.g. of FIG. 3A), except the topmost transistor T8, have a same low-frequency corner (superimposed plots). In the exemplary embodiment according to the present disclosure depicted in FIG. 3A, such low-frequency corner occurs at a frequency of 287.1 KHz, as indicated in the figure. To be noted that the low-corner frequency plots of FIG. 4 are obtained, for each transistor of the transistor stack, for a same total gate to common node resistance value (e.g. Rg) as compared to the prior art transistor stack depicted in FIG. 1A whose previously described corner frequency plots are depicted in FIG. 2.

By contrasting the plots of FIGS. 2 and 4, the person skilled in the art can appreciate the reduction in low-frequency corner provided by the reduced dissipation tree configuration according to the present disclosure over the prior art embodiment of the resistor gate biasing configuration. Such improvement, which is a frequency 16× lower (e.g. 4635/287.1) can in turn allow for a lower safe RF signal frequency of the reduced dissipation tree transistor stack as compared to the prior art embodiment while maintaining a same switching speed of the transistor stack, reducing RF power dissipation in the associated biasing circuit, and reducing the total die area for layout of the transistor stack.

FIG. 5 is a comparison chart of a performance of the prior art gate biasing versus a performance of the reduced dissipation tree gate biasing, as measured by various indicative operating parameters known to the person skilled in the art. By reading this chart, the person skilled in the art can appreciate that for a same switching speed (e.g., Tsw of 2.1 us) of the transistor stack, the reduced dissipation tree biasing configuration according to the teachings of the present disclosure can provide improvements in all the indicated operating parameters, including a reduced RF power dissipation, lower safe RF signal frequency of operation (low frequency corner), approximately half the resistor layout area, and therefore significantly less sensitivity to capacitive bypassing of gate resistors. Based on the comparison chart of FIG. 5, one can see, for example, that a product of a power dissipation and a switching speed for the reduced dissipation tree gate biasing according to the present disclosure is lower than a corresponding product for a prior art gate biasing of the transistor stack. Furthermore, the person skilled in the art will recognize that any RF power dissipation in a transistor stack (e.g., operating as a switch) due to the gate biasing network can reduce the effective quality factor Q of the transistor stack and therefore the reduced dissipation tree biasing configuration according to the teachings of the present disclosure can also provide a higher Q factor of a transistor stack due to the reduced RF power dissipation.

As mentioned in prior sections of the present disclosure, other biasing configurations using a resistor ladder string coupled to gate resistors as depicted in FIG. 3A can provide reduced RF power dissipation with the same advantages with respect to the prior art gate biasing configuration of FIG. 1A. Such reduced dissipation tree biasing configurations can use the same circuit as depicted in FIG. 3A but with different value resistors to address a desired design target. The person skilled in the art will understand that the present teachings can also extend to a transistor stack using transistors other than the exemplary FETs used in the present disclosure, and therefore such exemplary usage of FET transistors should not be construed as limiting the scope of the present invention.

According to a further embodiment of the present disclosure, a reduced dissipation tree biasing configuration according to the various embodiments of the present disclosure, such as the reduced dissipation tree biasing configuration shown in FIG. 3A, can be used in a transistor stack used in a digitally tunable capacitor (DTC). More information on a DTC can be found, for example, in the PCT publication number WO2009/108391 entitled “Method and Apparatus for use in Digitally Tuning a Capacitor in an Integrated Circuit Device”, published on Sep. 3, 2009, which is incorporated by reference herein in its entirety.

With further reference to the transistor stack of FIG. 3A, a reduced dissipation tree biasing configuration according to the present disclosure can simply seek to reduce power dissipation in the gate resistors (R8-R15) without necessarily providing a same total resistance between the gates of the transistors of the transistor stack and the common node (e.g. AC ground). This can allow providing a reduced dissipation tree for biasing the transistors of the transistor stack while controlling an effective gate resistance (from a transistor gate to the common node) to each of the transistors of the transistor stacked. Such embodiment can be provided, for example, by selecting values of the gate resistors (R8-R15) according to desired switching speeds of the associated transistors, while resistor values of the resistor ladder string (R1-R7) being selected to provide a same voltage at the gate resistors (R9-R15) (terminals away from the transistor gates) as the voltage at the gates of the corresponding transistors (T1-T7).

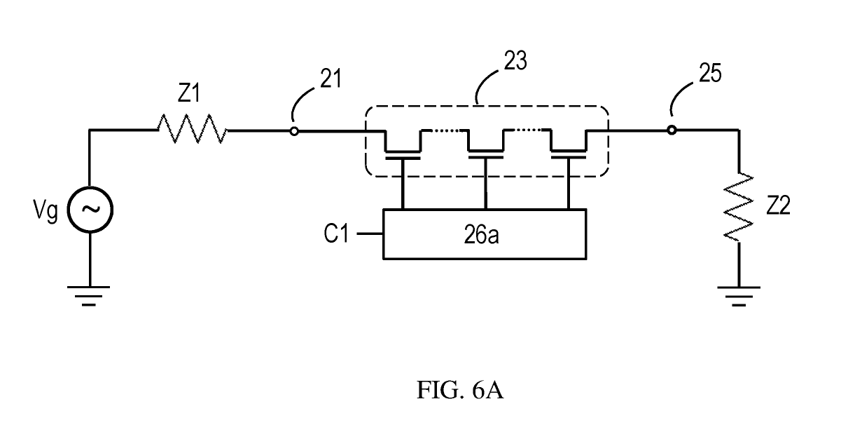

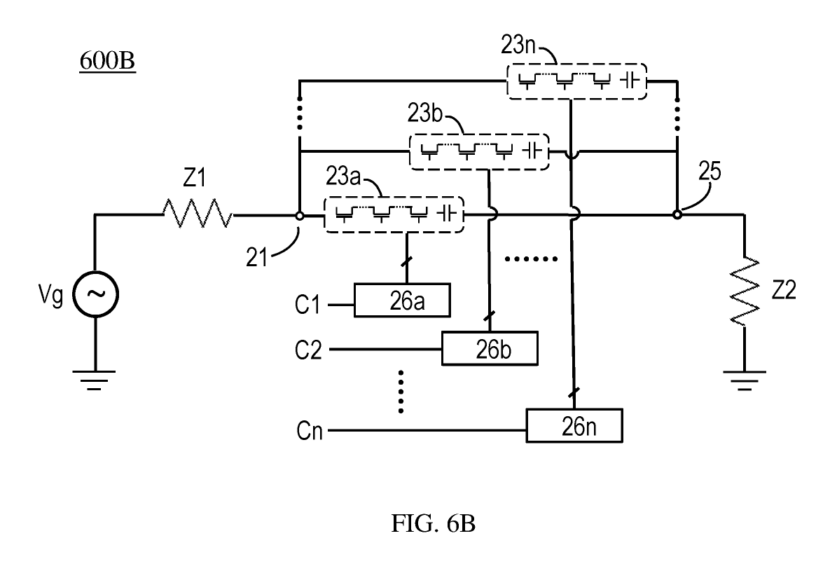

Although the exemplary transistor stack according to the present invention depicted in FIG. 3A shows the transistor stack connected in a shunt configuration, with the drain of the topmost transistor (T8) of the stack connected to an RF signal and the source of the bottommost transistor (T1) of the stack connected to a reference ground, other configurations as known to the skilled person are possible. As described below with reference to FIGS. 6A-6B, such configurations can result in an RF signal amplitude at the drain of the topmost transistor (T8) that is different from an RF signal amplitude at the source of the bottommost transistor (T1), and therefore a coupled RF signal amplitude at gate of the transistors of the transistor stack is based on a difference between the amplitudes at the drain of (T8) and the source of (T1). In such cases, the principle of operation of the inventive gate biasing of the transistor stack remains the same, including the reducing of the power dissipation across the gate resistors (R8-R15).

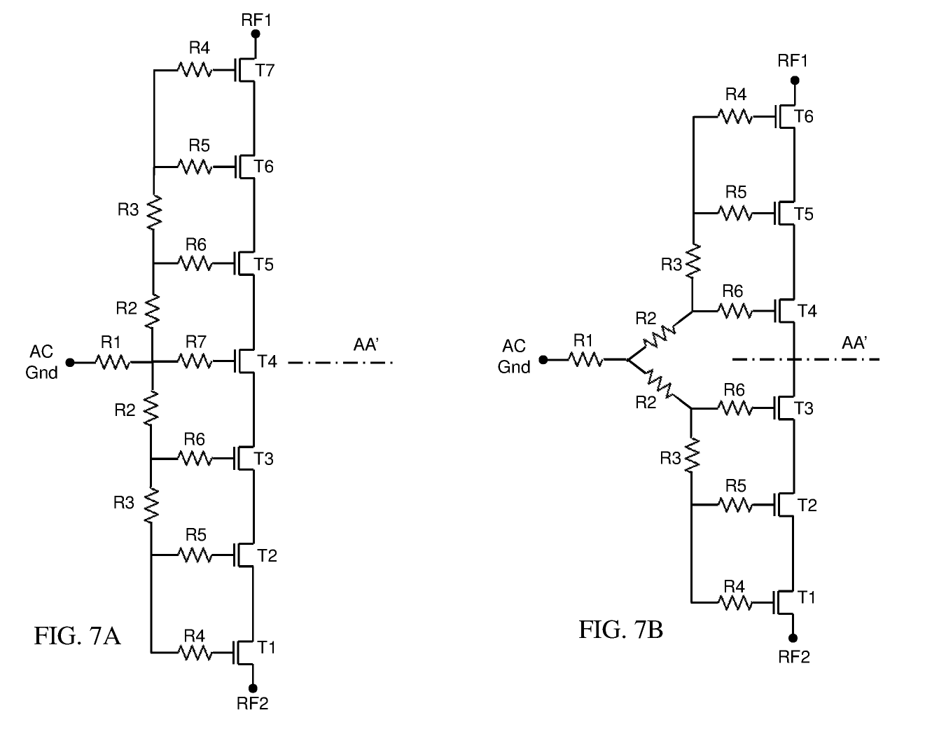

As discussed above in relation to the exemplary single pole double throw switch depicted in FIG. 1F, a transistor stack (e.g. 23, 24 of FIG. 1F) can be used in a series configuration where different RF signals (e.g. amplitudes) can be present at each of the opposing nodes of the transistor stack (e.g. drain of T8 and source of T1 of FIG. 3A). For example, when the transistor stack (23) is not conducting and the transistor stack (24) is conducting, RF signal amplitude at the common output terminal (25) can be dependent on the amplitude of the RF2 signal at terminal (22). Since the two signals RF1 and RF2 can be independent, relationship between their amplitudes cannot a priori be established, which means that the RF signal amplitude at the common output node (25) (which is one of the opposing nodes of the transistor stack 23) cannot be assumed to be smaller than, or larger than, the RF signal amplitude at the node 21 (which is the other of the opposing nodes of the transistor stack 23. It should be noted that the above reduced dissipation tree biasing embodiment of the transistor stack depicted in FIG. 3A assumes that the RF amplitude at the topmost transistor (T8) be larger than the RF amplitude at the bottommost transistor (T1). Alternative gate biasing circuits, herein labelled “symmetric”, are presented below, which while providing similar benefits to the above embodiment of FIG. 3A, can also allow operation irrespective to the RF amplitudes at the opposing nodes of the transistor stack, mainly due to the symmetrical nature of such gate biasing circuits with respect to a center of symmetry (AA′) of a corresponding tree, as depicted in FIGS. 7A-9 described below.

With further reference to the exemplary single pole double throw switch depicted in FIG. 1F, when the transistor stack (23) is conducting and the transistor stack (24) is not conducting, RF amplitudes at the opposing nodes (21, 25) of the transistor stack (23) can be dependent on an input impedance coupled to the node (21) and an output impedance coupled to the node (25). A corresponding circuital model is shown in FIG. 6A, where series connected transistor stack (23) is shown with the impedance Z1 coupled to the node (21) and impedance Z2 coupled to node (25). RF signal amplitude is shown to be generated by a voltage generator denoted Vg coupled to the impedance Z1. It is assumed that the transistor stack (24) is not conducting and therefore presents a high impedance (not shown) at node (25). A person skilled in the art will realize that the amplitude of RF signals at nodes (21) and (25) is a function of the impedances Z1 and Z2. For example, considering real valued impedances, if Z1=50Ω and Z2=0Ω, the transistor stack (23) is equivalent to a shunted transistor stack with the shunt (e.g. ground) at node (25) and a high RF voltage amplitude (substantially equal to Vg) at node (21), and if Z1=0Ω and Z2=50Ω, the transistor stack (23) is equivalent to a shunted transistor stack with the shunt at node (21) and a high RF voltage amplitude (substantially equal to Vg) at node (25). Alternatively, considering complex valued impedances (e.g. Z1=Z1_{R}+jZ1_{C} and Z1=Z1_{R}+jZ1_{C}), RF voltage amplitude at node (21) can be one of equal to, smaller than, and larger than an RF voltage amplitude at node (25), dependent on the complex valued impedances Z1 and Z2.

According to an exemplary embodiment of the present disclosure, the transistor stack (23) of FIG. 6A can be in series connection to one or more capacitors such as to define a (capacitor) bit of a digitally tunable capacitor (DTC), as explained, for example, in PCT publication number WO2009/108391 entitled “Method and Apparatus for use in Digitally Tuning a Capacitor in an Integrated Circuit Device”, published on Sep. 3, 2009, the disclosure of which is incorporated herein by reference in its entirety. An exemplary DTC (600B) is depicted in FIG. 6B, where the DTC comprises a plurality of selectable capacitor bits (23a, 23b, . . . , 23n) arranged in parallel across the nodes (21, 25). Each of the capacitor bits (23a, 23b, . . . , 23n) comprising a transistor stack in series connection with one or more capacitors defining a corresponding capacitive value of the capacitor bit, where the transistor stack is biased, by way of a corresponding gate biasing network (26a, 26b, . . . , 26n), according to a symmetric reduced dissipation tree gate biasing embodiment of the present disclosure.

Based on the above, it should be clear to a person skilled in the art that when used in a series configuration, such as depicted in FIGS. 6A-6B, (as opposed to the shunted configuration depicted in FIG. 3A), RF voltage amplitudes at the opposing nodes of the series transistor stack can have any relationship, dictated, for example, by impedance coupling to the opposing nodes when the transistor stack is conducting, or by coupled RF signals to the opposing nodes when the transistor stack in not conducting. As the exemplary reduced dissipation tree gate biasing according to the present disclosure depicted in FIG. 3B assumes one of the opposing nodes (e.g. drain of T8) to always carry an RF signal with a larger amplitude than an amplitude of an RF signal at the other opposing node (e.g. source of T1), a transistor stack (e.g. T1-T8 of FIG. 3A) using such gate biasing would generally not operate as conceived if used in a series configuration (where RF voltage amplitudes at either of the opposing nodes may be larger). It is therefore an object of the present disclosure to provide a reduced dissipation tree gate biasing circuit for a transistor stack operating in a series configuration, with improved performance, as measured by a reduction in power dissipation of the RF voltage amplitudes at the opposing nodes of the transistor stack. Various exemplary embodiments according to the present disclosure of such reduced dissipation tree gate biasing circuit are depicted in FIGS. 7A-9 described below.

FIG. 7A is a simplified circuit diagram according to an embodiment of the present disclosure of a symmetric reduced dissipation tree gate biasing configuration of an exemplary transistor stack comprising an odd number (e.g. seven) of transistors (T1-T7) which can provide a same reduction in power dissipation irrespective of an RF voltage amplitude at the opposing nodes (RF1, RF2) of the transistor stack. Such performance is achieved by designing a symmetrical gate biasing circuit around an axis of symmetry of the transistor stack, denoted by AA′ in the FIG. 7A, where resistor values of resistors placed in symmetry with respect to the axis of symmetry AA′ are substantially equal. In the case of the transistor stack of FIG. 7A, the axis of symmetry AA′ passes through the middle transistor T4 of the transistor stack and the common AC ground node. The gate biasing circuit comprises resistors arranged symmetrically around the axis of symmetry AA′, with corresponding resistance values following the symmetry. The symmetric gate biasing circuit of FIG. 7A comprises a symmetric (with respect to axis AA′) resistor tree (R1, R2, R2, R3, R3) coupled to gate resistors (R4, R5, R6, R7, R6, R5, R4) via nodes of the resistor tree. The resistor tree comprises a resistor ladder string (R3, R2, R2, R3), coupled at a center node of the resistor ladder string to the resistor R1. The center of the symmetry comprises transistors T4, gate resistor R7 and resistor R1 of the resistor tree which couples the resistor tree to the common AC ground node. The person skilled in the art readily realizes that the configuration depicted in FIG. 7A can be expanded to any odd transistor stack height where a middle transistor of the stack defines the axis of symmetry AA′.

With further reference to the transistor stack depicted in FIG. 7A, according to an embodiment of the present disclosure, the effective gate resistance from a gate of any of the transistors of the transistor stack (T1-T7) to the common AC ground can be designed to be constant for a desired constant switching speed of the transistors of the transistor stack. Furthermore, due to the symmetrical nature of the gate biasing circuit depicted in FIG. 7A, any reduction of the power dissipation in an upper gate resistor (with respect to the axis AA′) of the gate biasing circuit for an RF voltage amplitude at node RF1 larger than an RF voltage amplitude at node RF2, provides an equivalent reduction of the power dissipation in a corresponding lower resistor (symmetrical to the upper resistor with respect to the axis AA′) for an RF voltage amplitude at node RF2 larger than an RF voltage amplitude at node RF1. In other words, contrary to the exemplary embodiment according to the present disclosure depicted in FIG. 3A, the symmetric reduced dissipation tree gate biasing circuit of FIG. 7A provides a same performance (reduction in power dissipation) irrespective of the RF voltage values at the opposing nodes (RF1, RF2) of the corresponding transistor stack.

As previously described in relation to the power reduction for the gate biasing circuit of FIG. 3A, reduction in power dissipation in a resistor (e.g. gate resistor) of the symmetric gate biasing circuit of FIG. 7A can be provided by first dividing, via the resistor tree, a voltage at a top node of the transistor stack, and coupling the resistor tree to the gate resistors, as shown in FIG. 7A, thereby providing a zero voltage drop across one or more of the gate resistors for a reduction in power dissipation in the one or more gate resistors. Selection of the resistor values can be performed by assuming a higher voltage at one of the two opposing nodes (RF1, RF2), and based on such assumption, selecting the resistor values in a corresponding half of the gate biasing circuit in order to reduce power dissipation using same methods as described in relation to power reduction in the embodiment depicted in FIG. 3A.

FIG. 7B is a simplified circuit diagram according to an embodiment of the present disclosure of a symmetric reduced dissipation tree gate biasing configuration of an exemplary transistor stack comprising an even number (e.g. six) of transistors (T1-T6) which can provide a same reduction in power dissipation irrespective of an RF voltage amplitude at the opposing nodes (RF1, RF2) of the transistor stack. Principle of operation of the exemplary embodiment depicted in FIG. 7B is same as the embodiment of FIG. 7A discussed above. In the case of the embodiment depicted in FIG. 7B and due to the even values stack height, the axis of symmetry AA′ does not pass through a middle transistor and only comprises the resistor R1 which couples the symmetric resistor tree (R1, R2, R2, R3, R3) to the common AC ground node. As can be seen in FIG. 7B, the symmetric resistor tree (R1, R2, R2, R3, R3) can be considered as a resistor ladder string (R3, R2, R2, R3) whose center node is coupled to the AC ground via resistor R1, and whose nodes, except the center node, are coupled to the gate resistors (R4, R5, R6, R6, R5, R4) of the transistor stack.

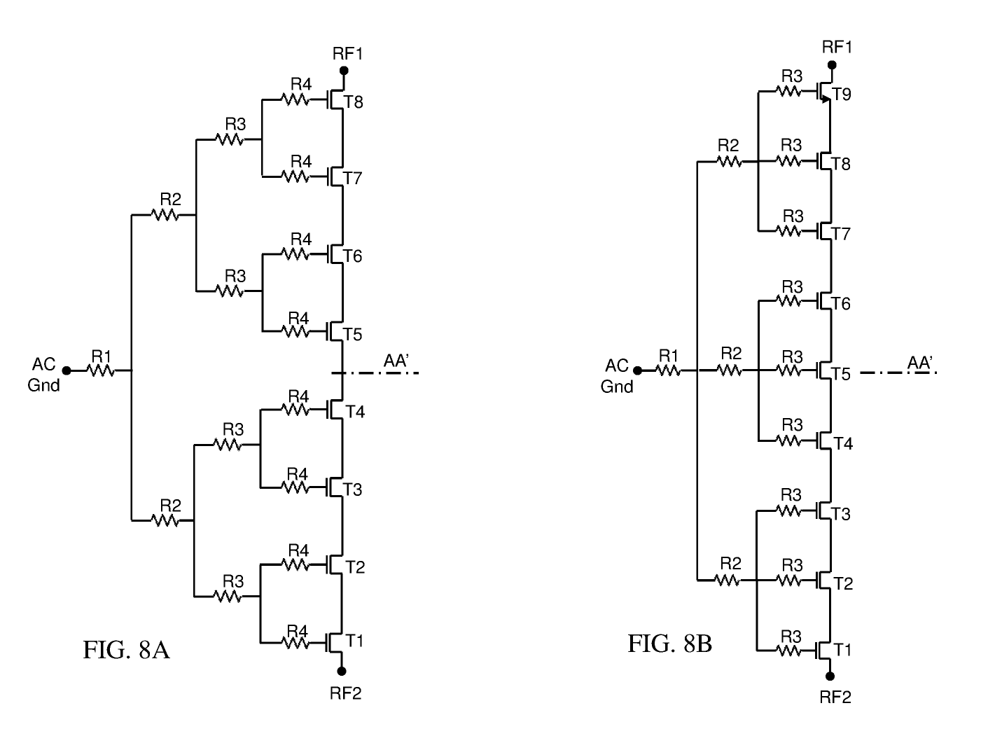

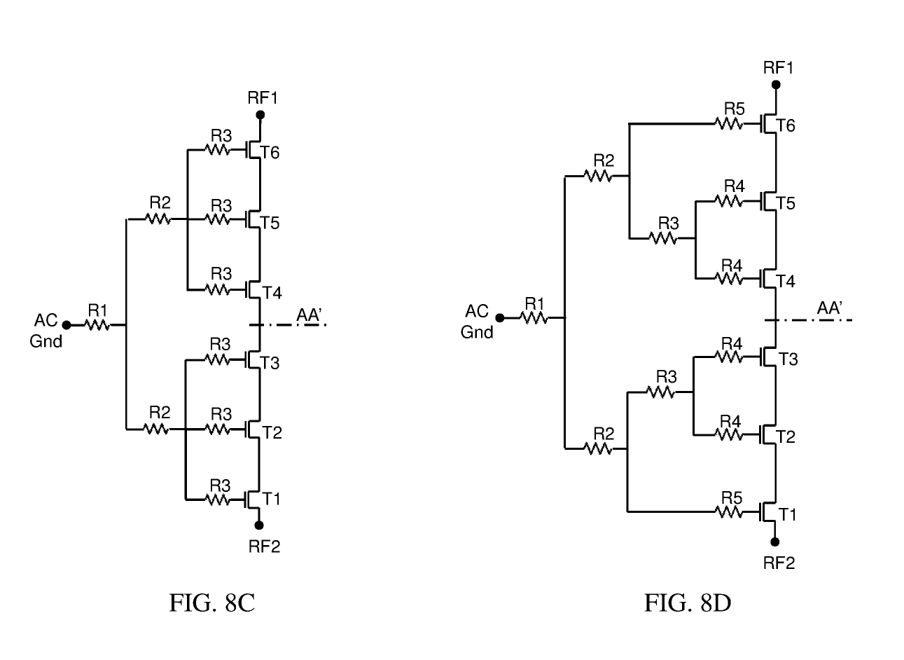

The exemplary symmetric reduced dissipation tree gate biasing circuits of FIGS. 7A and 7B comprise symmetric resistor trees coupled to the gate resistors of the transistors of the transistor stack, and coupled to the common AC ground node via a single resistor (e.g. R1) at the center of the tree. Applicant of the present disclosure has established other gate biasing circuits comprising resistors arranged symmetrically with respect to an axis of symmetry which can likewise provide a reduction in power dissipation in one or more branches of the tree irrespective of the RF voltage amplitude at the opposing nodes (RF1, RF2) of the transistor stack, while providing a desired (e.g. constant) effective gate resistance to each of the transistors of the transistor stack. Such symmetric reduced dissipation tree gate biasing circuits according to exemplary embodiments of the present disclosure are depicted in FIGS. 8A-8D. It should be noted that for simplicity reasons, such exemplary embodiment are provided with specific stack heights (e.g. 8, 9, 6) which should not be considered as limiting the scope of the present invention. Based on the provided teachings and the presented exemplary embodiments, it is well within the reach of the person skilled in the art to expand such exemplary embodiments to configurations comprising different transistor stack heights.

As can be seen the exemplary embodiments of the present disclosure depicted in FIGS. 8A-8D, such symmetric reduced dissipation tree gate biasing circuits include a plurality of resistors forming a resistor tree, where the resistors form different resistor levels, each resistor level comprising a same value resistance (e.g. R1, R2, R3, R4, . . . ). The different resistor levels are coupled to each other via nodes formed by joining two or more resistors of one resistor level with one resistor of a next resistor level. This is depicted, for example, in the exemplary embodiment of FIG. 8A, where a first resistor level is defined by the resistor R1, a second resistor level is defined by the two resistors R2, a third resistor level is defined by the four resistors R3, and a fourth resistor level is defined by the eight (gate) resistors R4. Starting from the fourth resistor level which is coupled, via each of the resistors R4, to the gates of the transistors (T1-T8) of the transistor stack, two such resistors R4 are coupled to a same resistor R3 of the third resistor level. In turn, two resistors R3 of the third resistor level are coupled to a same resistor R2 of the second resistor level, and finally, the two resistors R2 of the second resistor level are coupled to the single resistor R1 of the first resistor level which is used as the final link to couple the resistor tree to the common AC ground.

With further reference to the exemplary embodiment depicted in FIG. 8A, each resistor level comprises 2^{N} resistors (e.g. 2³, 2², 2¹, 2⁰, for level 3 (resistors R4), level 2 (resistors R3), level 1 (resistors R2), and level 0 (resistor R1)) which are coupled via 2^{N} nodes to a higher resistor level and via 2^{N-1} nodes to a lower resistor level. Each resistor level divides nodes to the higher resistor level by two to provide nodes to the lower resistor level. The applicant of the present disclosure has defined the exemplary symmetric reduced dissipation tree gate biasing circuit of FIG. 8A as a 3-level, secondary (e.g. binary) symmetric tree, as it includes three resistor levels (levels 1-3) prior to merging to the common AC ground coupling resistor R1 (level 0), and each resistor level performs a divide by two operation of nodes to a higher resistor level to provide nodes to a lower resistor level by joining (merging) of two resistors of the each resistor level (thereby providing a merging node that becomes a node of the lower resistor level. Other exemplary embodiments, such as the 2-level, tertiary symmetric tree depicted in FIG. 8B are possible and within the reach of the person skilled in the art in view of the present teachings.

Although the number of resistor levels and the performed operation in each of the resistor levels with respect to converting nodes from a higher level to nodes from a lower level (e.g. divide by two as per FIG. 8A, divide by three as per FIG. 8B) can follow specific fixed patterns, as depicted in FIGS. 8A-8B, some embodiments according to the present disclosure can allow mixed patterns or even arbitrary patterns to be used in a symmetrical fashion with respect to an axis of symmetry AA′ of the tree.

An exemplary embodiment according to the present disclosure of a 2-level mixed symmetric tree is shown in FIG. 8C, where the third resistor level comprising resistors R3 performs a divide by three (tertiary) operation (three resistor branches R3 coupled to divide gate nodes to nodes to a lower level) and the second resistor level comprising resistors R2 performs a divide by two (secondary) operation (two resistors R2 coupled to divide nodes from higher level to nodes to lower level).

An exemplary embodiment according to the present disclosure of an arbitrary symmetric tree is shown in FIG. 8D where symmetric arrangements on top and bottom of the axis AA′ are provided to allow a reduction of power in one or more of the resistors irrespective of the RF voltage amplitude at nodes (RF1, RF2).

A power reduction scheme for a symmetric reduced dissipation tree gate biasing according to the present disclosure can seek to provide a same voltage at both terminals of one or more resistors, thereby creating a virtual open circuit (neither sinks nor sources current), by an appropriate selection of the various resistor values of the tree, similar to the scheme used in reducing power dissipation in the reduced dissipation tree gate biasing depicted in FIG. 3A with the added constraint of symmetry around the axis AA′ (e.g. FIGS. 7A-8D), and, in some cases, a same resistor value for a same resistor level (e.g. FIGS. 8A-8C).

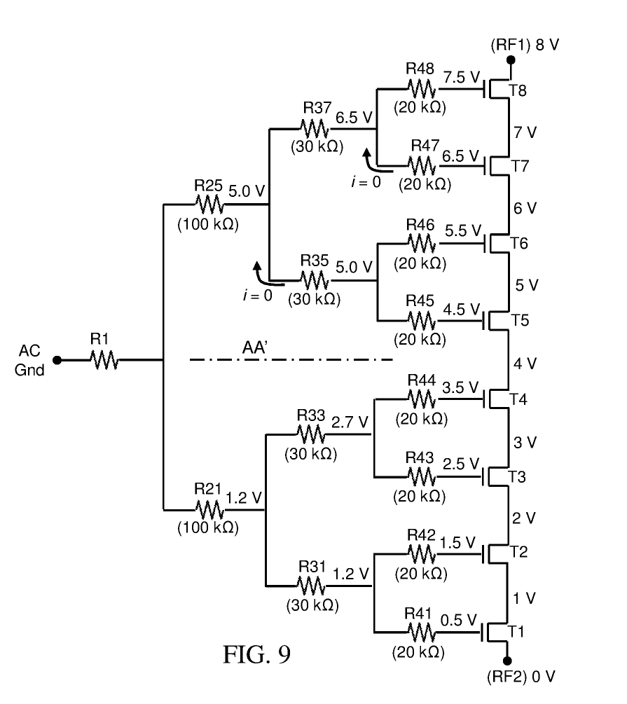

FIG. 9 depicts an exemplary power reduction scheme for the 3-level, secondary symmetric reduced dissipation tree gate biasing circuit of FIG. 8A. As described above in relation to FIG. 8A, such tree comprises four resistor levels, a first resistor level comprising the resistor R1, a second resistor level comprising resistors (R21, R25) of a same resistance value (e.g. 100 kΩ), a third resistor level comprising resistors (R31, R33, R35, R37) of a same resistance value (e.g. 30 kΩ), and a fourth resistor level comprising (gate) resistors (R41-R48) of a same resistance value (e.g. 20 kΩ), where the fourth resistor level is coupled, via the gate resistors (R41-R48), to the transistors (T1-T8) of the transistor stack.

With further reference to FIG. 9, when the transistor stack (T1-T8) is in the OFF state, voltage amplitude of an RF signal at the drain of the topmost transistor T8 (node RF1) is assumed to be 8 volts (8V) and voltage amplitude of an RF signal at the source of the bottommost transistor T1 is assumed to be 0 volts (0V). These voltages can represent a voltage differential between voltages at the nodes RF1 and RF2, further normalized with respect to the number of transistors in the transistor stack (8) for providing easy to manipulate voltages as seen in FIG. 9. Voltage division of the voltage differential (8V) across the eight transistors (T1-T8) provides voltages (1V, 2V, . . . , 7V) at common source-drain nodes of the transistors (T1-T8), while capacitive coupling (e.g. C_{DG-OFF}) of each of the transistors provides gate voltages (0.5V, 1.5V, . . . , 7.5V) at each of the gates of the transistors (T1-T8), starting from the topmost transistor T8 and rippling down to the bottommost transistor T1.

As noted above, a power reduction scheme can seek to minimize power dissipation in one or more of the resistors of the tree. In the particular case represented in FIG. 9, no current goes through resistors R47 and R35 and therefore zero power is dissipated by these resistors. This can be obtained by selecting the values of the resistors (R48, R37, R25, R1), which form a resistor string between the gate of the transistor T8 carrying 7.5 volts and the common AC ground node, to provide a voltage equal to 6.5 volts at the common node between resistor R47 and resistor R37, and to provide a voltage equal to 5.0 volts at the common node between resistors R35 and R25, as shown in FIG. 9. Such resistor values may also reflect an added constraint with respect to the effective gate resistor of transistor T1 (e.g. R1+R25+R37+R48=Rₑ). It should be noted that since the higher transistors, and therefore the corresponding higher resistors of the gate biasing circuit, see higher voltages (as depicted in FIG. 9), it can be advantageous to minimize current flow through such higher resistors for a greater reduction in power dissipation.

The person skilled in the art readily realizes that the minimization scheme presented above with reference to FIG. 9 is one of many possible schemes for a symmetric gate biasing according to the present invention. Other schemes may be derived which while not providing virtual current nodes (no current through a resistor) may altogether reduce power dissipation in the symmetric gate biasing circuit of the present invention, and therefore be used in biasing transistors stacks operating in either shunted or series configurations with a same reduction in power dissipation while maintaining a desired (e.g. equal) switching speed (e.g. time) of the transistors of the transistor stacks.

From the above teachings, it follows that a desired gate biasing (provided by the gate biasing networks (26c, 26d)) for the shunted transistor stacks (27, 28) of the single pole double throw RF switch of FIG. 1F can be according to the reduced dissipation tree gate biasing embodiment depicted in FIG. 3A, while a desired gate biasing (provided by the gate biasing networks (26a, 26b)) for the series connected transistor stacks (23, 24) of said RF switch can be according to any of the symmetric reduced dissipation tree gate biasing embodiments depicted in FIGS. 7A-8D.

With this description, we have fully disclosed a novel resistor tree approach for biasing gates of a transistor stack which can reduce power dissipation in the transistor stack, whether used in a shunted or series configuration.

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

It may be possible to execute the activities described herein in an order other than the order described. Various activities described with respect to the methods identified herein can be executed in repetitive, serial, or parallel fashion.

The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived there-from, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein individually or collectively by the term “invention” merely for convenience and without intending to voluntarily limit the scope of this application to any single invention or inventive concept, if more than one is in fact disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the present disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In the foregoing Detailed Description, various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

1. A circuit arrangement comprising:
a stack of series connected transistors comprising a top transistor, at least one intermediate transistor and a bottom transistor;
a plurality of gate resistors, each coupled at a first end to a gate of a respective transistor of said top transistor, at least one intermediate transistor and said bottom transistor; and
a resistor ladder string to which a second end of each of said gate resistors is coupled,
wherein a bottom of said resistor ladder string is coupled to AC ground.

2. The circuit arrangement of claim 1, wherein the stack of series connected transistors receives a radio frequency input at one of a top transistor source and a top transistor drain of said top transistor.

3. The circuit arrangement of claim 2, wherein the stack of series connected transistors couples to AC ground at one of a bottom transistor source and a bottom transistor drain of said bottom transistor.

4. The circuit arrangement of claim 2, wherein when the stack of series connected transistors do not conduct current, a voltage of the radio frequency input is divided across the stack of series connected transistors.

5. The circuit arrangement of claim 3, wherein when the stack of series connected transistors do not conduct current, a voltage of the radio frequency input is divided across the stack of series connected transistors.

6. The circuit arrangement of claim 4, wherein a voltage drop across at least one gate resistor of said plurality of gate resistors is less than a gate voltage on a respective transistor of said stack of series connected transistors.

7. The circuit arrangement of claim 5, wherein a voltage drop across at least one gate resistor of said plurality of gate resistors is less than a gate voltage of a respective transistor of said stack of series connected transistors.

8. The circuit arrangement of claim 6, wherein the voltage drop across the at least one gate resistor is approximately zero.

9. The circuit arrangement of claim 7, wherein the voltage drop across the at least one gate resistor is approximately zero.

10. The circuit arrangement of claim 8, wherein the voltage drop across a gate resistor coupled to the top transistor is non-zero and the voltage drop across each of the plurality of gate resistors coupled to a respective transistor of the stack of series connected transistors different from the top transistor is approximately zero.

11. The circuit arrangement of claim 9, wherein the voltage drop across a gate resistor coupled to the top transistor is non-zero and the voltage drop across each of the plurality of gate resistors coupled to a respective transistor of the stack of series connected transistors different from the top transistor is approximately zero.

12. The circuit arrangement of claim 2, wherein a resistive impedance between respective gates of said stack of series connected transistors and AC ground is approximately the same.

13. The circuit arrangement of claim 3, wherein a resistive impedance between respective gates of said stack of series connected transistors and AC ground is approximately the same.

14. The circuit arrangement of claim 2, wherein a product of a power dissipation and a switching speed of said circuit arrangement is lower than a product of a power dissipation and a switching speed of a different circuit arrangement comprising a stack of series connected transistors and gate resistors connected directly to AC ground.

15. The circuit arrangement of claim 3, wherein a product of a power dissipation and a switching speed of said circuit arrangement is lower than a product of a power dissipation and a switching speed of a different circuit arrangement comprising a stack of series connected transistors and gate resistors connected directly to AC ground.

16. The circuit arrangement of claim 3, wherein a sum of impedances of the plurality of gate resistors and resistor ladder string is less than a product of an effective impedance from any gate of a transistor of the stack of series connected transistors to AC ground multiplied by a number of transistors in the stack of series connected transistors.

17. The circuit arrangement of claim 3, wherein the stack of series connected transistors is utilized as a switch.

18. The circuit arrangement of claim 3, wherein the stack of series connected transistors is utilized in a digitally tunable capacitor.

19. A method of reduced dissipation FET gate biasing in a stack of series connected transistors comprising:
splitting a series of voltage drops in at least one resistor ladder string stage;
providing a series of gate voltages to said stack of series connected transistors from said series of voltage drops from said at least one resistor ladder string stage to a gate resistor stage; and
approximately equalizing an effective gate impedance from a gate of a transistor to AC ground for transistors in said stack of series connected transistors from said gate resistor stage through said at least one ladder resistor stage to AC ground.

20. The method of claim 19 further comprising receiving a radio frequency input to a source or a drain of said stack of series connected transistors.

21. The method of claim 20 further comprising dividing a voltage of the radio frequency input across said stack of series connected transistors when said stack of series connected transistors is in a non-conducting state.

22. A circuit arrangement comprising:
a stack of series connected transistors comprising a top transistor, at least one intermediate transistor and a bottom transistor;
a plurality of gate resistors coupled at a first end to a gate of a respective transistor of said top transistor, at least one intermediate transistor and said bottom transistor;
a resistor ladder string to which a second end of each of said gate resistors is coupled, and
an AC ground resistively coupled to all gates of the stack of series connected transistors.

23. The circuit arrangement of claim 22, wherein the stack of series connected transistors is configured to receive a radio frequency input at one of a top transistor source and a top transistor drain of said top transistor and at one of a bottom transistor source and a bottom transistor drain of said bottom transistor.

24. The circuit arrangement of claim 23, wherein when the stack of series connected transistors do not conduct current, a voltage of the radio frequency input is divided across the stack of series connected transistors.

25. The circuit arrangement of claim 24, wherein a voltage drop across at least one gate resistor of said plurality of gate resistors is less than a gate voltage of a respective transistor of said stack of series connected transistors.

26. The circuit arrangement of claim 25, wherein the voltage drop across at least one gate resistor is approximately zero.

27. The circuit arrangement of claim 26, wherein the voltage drop across two gate resistors of the plurality of gate resistors is non-zero and the voltage drop across a remaining portion of the plurality of gate resistors is approximately zero.

28. The circuit arrangement of claim 23, wherein a resistive impedance between respective gates of said stack of series connected transistors and AC ground is approximately the same.

29. The circuit arrangement of claim 23, wherein a sum of impedances of the plurality of gate resistors and resistor ladder string is less than a product of an effective impedance from any gate of a transistor of the stack of series connected transistors to AC ground multiplied by a number of transistors in the stack of series connected transistors.

30. The circuit arrangement of claim 23, wherein the stack of series connected transistors is utilized as a switch.

31. The circuit arrangement of claim 23, wherein the stack of series connected transistors is utilized in a digitally tunable capacitor.

32. A method of reduced dissipation FET gate biasing in a stack of series connected transistors, comprising:
symmetrically splitting a series of voltage drops in at least one resistor ladder string stage from a center AC ground;
providing a series of gate voltages to said stack of series connected transistors from said series of voltage drops from said at least one resistor ladder string stage to a gate resistor stage; and
approximately equalizing an impedance for transistors in said stack of series connected transistors from said gate resistor stage through said at least one ladder resistor stage to said center AC ground.

33. The method of claim 32 further comprising receiving a radio frequency input to a source or a drain of said stack of series connected transistors.

34. The method of claim 33 further comprising dividing a voltage of the radio frequency input across said stack of series connected transistors when said stack of series connected transistors is in a non-conducting state.

35. A circuit arrangement comprising:
a stack of series connected transistors; and
a resistor tree,
wherein the resistor tree comprises a plurality of resistor levels, each resistor level having one or more resistors each separately connected to two or more resistors of a subsequent resistor level, the resistors of the last resistor level each being a gate resistor connected to a respective gate of a plurality of transistors of the stack of series connected transistors, and
wherein the one or more resistors of a first resistor level are a single resistor connected to two or more resistors of the second resistor level at one end and to AC ground at the other end.

36. The circuit arrangement of claim 35, wherein the resistor tree is symmetrical with respect to a center transistor of said stack of series connected transistors.

37. The circuit arrangement of claim 36, wherein the stack of series connected transistors receives a radio frequency input at at least one of a top end of said stack of series connected transistors and a bottom end of said stack of series connected transistors.

38. The circuit arrangement of claim 36, wherein the stack of series connected transistors receives a radio frequency input at a top end of said stack of series connected transistors and is coupled to AC ground at a bottom end of said stack of series connected transistors.

39. The circuit arrangement of claim 37, wherein, when not conducting current, the stack of series connected transistors divides a voltage across a set of sources and a set of drains of said stack of series connected transistors.

40. The circuit arrangement of claim 38, wherein, when not conducting current, the stack of series connected transistors divides a voltage across a set of sources and a set of drains of said stack of series connected transistors.

41. The circuit arrangement of claim 37, wherein the stack of series connected transistors divides a voltage across a set of gates of said stack of series connected transistors.

42. The circuit arrangement of claim 38, wherein the stack of series connected transistors divides a voltage across a set of gates of said stack of series connected transistors.

43. The circuit arrangement of claim 39, wherein a maximum voltage drop across respective gate resistors of said stack of gate resistors is less than a voltage difference between a maximum gate voltage and AC ground.

44. The circuit arrangement of claim 40, wherein a maximum voltage drop across respective gate resistors of said stack of gate resistors is less than a voltage difference between a maximum gate voltage and AC ground.

45. The circuit arrangement of claim 41, wherein a maximum voltage drop across respective gate resistors of said stack of gate resistors is less than a voltage difference between a maximum gate voltage and AC ground.

46. The circuit arrangement of claim 42, wherein a maximum voltage drop across respective gate resistors of said stack of gate resistors is less than a voltage difference between a maximum gate voltage and AC ground.

47. The circuit arrangement of claim 37, wherein a sum of impedances from the resistor tree to AC ground is less than a product of an effective impedance of the stack of series connected transistors multiplied by a number of the stack of series connected transistors.

48. The circuit arrangement of claim 38, wherein a sum of impedances from the resistor tree to AC ground is less than a product of an effective impedance of the stack of series connected transistors multiplied by a number of the stack of series connected transistors.

49. The circuit arrangement of claim 37, wherein the stack of series connected transistors is utilized as a switch.

50. The circuit arrangement of claim 38, wherein the stack of series connected transistors is utilized as a switch.

51. The circuit arrangement of claim 37, wherein the stack of series connected transistors is utilized in a digitally tunable capacitor.

52. The circuit arrangement of claim 38, wherein the stack of series connected transistors is utilized in a digitally tunable capacitor.

53. A method of reduced dissipation FET gate biasing in a stack of series connected transistors comprising:
symmetrically splitting in levels a series of voltage drops in a resistor tree;
providing a series of gate voltages to said stack of series connected transistors from said series of voltage drops from said resistor tree to a gate resistor stage; and
approximately equalizing an impedance for transistors in said stack of series connected transistors from said gate resistor stage through said resistor tree to AC ground.

54. The method of claim 53 further comprising, receiving a radio frequency input at a first end of said stack of series connected transistors and a second end of said stack of series connected transistors.

55. The method of claim 53 further comprising, receiving a radio frequency input at a first end of said stack of series connected transistors.
